(19) United States
(12) Patent Application Publication
(10) Pub. No.: US 2005/0011460 A1
(43) Pub. Date: Jan. 20, 2005

(54) Substrate chucking apparatus

(75) Inventor: Yoshihisa Taniguchi, Okaya-shi (JP)

Correspondence Address: FRISHAUF, HOLTZ, GOODMAN & CHICK, PC, 767 THIRD AVENUE, 25TH FLOOR, NEW YORK, NY, 10017-2023, US

(73) Assignee: Olympus Corporation, Tokyo (JP)

(21) Appl. No.: 10/916,237

(22) Filed: Aug. 11, 2004

Related U.S. Application Data
(63) Continuation of application No. PCT/JP03/01645, filed on Feb. 17, 2003.

(30) Foreign Application Priority Data
Feb. 19, 2002 (JP) 2002-041821

(51) Int. Cl. C23C 16/00

(52) U.S. Cl. 118/728

(57) ABSTRACT

Correcting pads, each having a vertically movable pad and an elastic member which is expanded and contracted by a negative pressure generated by air exhaust and moves the pad vertically, are arranged along an outermost peripheral portion of an entire-surface chucking portion.

### CROSS-REFERENCE TO RELATED APPLICATIONS

This is a Continuation Application of PCT Application No. PCT/JP03/01645, filed Feb. 17, 2003, which was published under PCT Article 21(2) in Japanese.

This application is based upon and claims the benefit of priority from prior Japanese Patent Application No. 2002-041821, filed Feb. 19, 2002, the entire contents of which are incorporated herein by reference.

### BACKGROUND OF THE INVENTION

1. Field of the Invention

The present invention relates to a substrate chucking apparatus for chucking and holding, e.g., a semiconductor wafer and a glass substrate in a flat panel display (FPD) such as a liquid crystal display.

2. Description of the Related Art

FIG. 12 is a plan view showing the structure of a substrate chucking apparatus, and FIG. 13 is a side view of the same. A plurality of grooves 2 are formed in a chucking surface 1 and communicate with an exhaust port 4 through an exhaust path 3. The exhaust port 4 is connected to an exhaust means (not shown) such as a vacuum pump. When the exhaust means performs an air suction operation, a substrate 5 is chucked by vacuum onto the chucking surface 1.

When, however, the substrate (semiconductor wafer) 5 becomes large in size and decreases in profile, as the chucking surface l is smaller than the substrate 5, the substrate 5 is deflected by its own weight such that the closer to the outer peripheral portion, the more downward it is deflected.

While the substrate 5 is deflected in this manner, when the surface of the substrate 5 is to be observed with a microscope, the focal point of the microscope is shifted undesirably at the deflected portion of the substrate 5. While the substrate 5 is deflected, when the substrate 5 is to be subjected to various types of processes, e.g., when a circuit pattern is to be exposed on the substrate 5 during a photolithography manufacturing process, the image of the circuit pattern becomes out of focus at the deflected portion of the substrate 5.

To solve the problems caused by the deflection of the substrate 5, a technique for chucking the entire surface of the substrate 5 to maintain its flatness is described in, e.g., Jpn. Pat. Appln. KOKAI Publication Nos. 6-132387 and 2000-311933.

FIG. 15 is a plan view showing the structure of a substrate chucking apparatus, and FIG. 16 is a partial enlarged view of the same. A projecting bank 7 is formed on the outermost peripheral portion of an entire-surface chucking portion 6. The bank 7 serves as a chucking pad which maintains hermeticity between a substrate 5 and the entire-surface chucking portion 6 when a notched semiconductor wafer is placed as a substrate 5 on the entire-surface chucking portion 6, and chucks the entire surface of the substrate 5.

A plurality of exhaust holes 10 are formed in the upper surface of the entire-surface chucking portion 6, and communicate with a corresponding one of exhaust channels 11-1 to 11-4. The respective exhaust channels 11-1 to 11-4 are connected to an exhaust device (not shown) through joints 12-1 to 12-4 arranged on the outer peripheral portion of the entire-surface chucking portion 6.

When the substrate 5 is placed on a chucking surface 9 of the entire-surface chucking portion 6, it is chucked and held on the entire-surface chucking portion 6 by air exhaust of the exhaust device while maintaining the flatness of the substrate 5.

If the substrate 5 warps, e.g., upward as shown in FIG. 17, a gap 15 is formed between the outer peripheral portion of the substrate 5 and the bank 7 which serves as the chucking pad. With the gap 15 being present, when suction is started through the exhaust holes 10, external air flows in through the gap 15, and the substrate 5 cannot be chucked onto the chucking surface 9.

FIG. 18 is a view showing the structure of a chucking pad described in Jpn. Pat. Appln. KOKAI Publication No. 8-229866. A pedestal member 16 is mounted in a mounting recess 18 of a base 17. A chucking member 19 is fitted on the pedestal member 16, and is biased upward by a coil spring 20. The pedestal member 16 and chucking member 19 form a labyrinth structure with the fitting portions of a center hole 21, annular groove 22, support shaft portion 23, and sleeve member 24. A plurality of such chucking pads are arranged on the base 17 in a juxtaposed manner.

The chucking member 19 can be slightly inclined with respect to the support shaft portion 23 as the center, and is mounted retractably through the coil spring 20. In this manner, when the chucking member 19 is formed retractably, even if the substrate 5 warps, it can be chucked when the chucking surface protrudes.

The plurality of chucking pads are arranged on the base 17 in a juxtaposed manner, and serve to chuck and hold the substrate 5 with the chucking members 19 of the respective chucking pads but cannot chuck and hold the entire surface of the substrate. Thus, the substrate 5 cannot be kept flat.

It is an object of the present invention to provide a substrate chucking apparatus which can chuck and hold a substrate with its entire surface, can improve the flatness of the surface, and can chuck and hold the substrate reliably even when the substrate warps.

### BRIEF SUMMARY OF THE INVENTION

According to an aspect of the present invention, there is provided a substrate chucking apparatus comprising: an entire-surface chucking portion which includes a chucking surface that chucks and holds a substrate to maintain flatness of the substrate, and has a hole portion formed at a central portion; a substrate transfer portion which is arranged in the hole portion of the entire-surface chucking portion to up/down possible, and chucks and holds the substrate and up/downs, to transfer the substrate with respect to the entire-surface chucking portion; and at least three correcting pad portions which includes cylindrical pads and tubular elastic members, the cylindrical pads are arranged along an outermost peripheral portion of the entire-surface chucking portion and up/down possible with respect to the chucking surface of the entire-surface chucking portion, and formed a suction-cup-shaped upper portion, the tubular elastic member swingably supports the cylindrical pads when the elastic member moves upward, the at least three correcting pad portions correcting the substrate so as to be parallel to the entire-surface chucking portion when a negative pressure generated upon chucking of the substrate collapses the elastic members.

### BRIEF DESCRIPTION OF THE SEVERAL VIEWS OF THE DRAWING

FIG. 1 is a plan view showing the structure of a substrate chucking apparatus according to a first embodiment of the present invention;

FIG. 2 is a sectional view of the structure taken along the line X-X of the apparatus of FIG. 1;

FIG. 3 is an enlarged view showing the structure of a correcting pad portion of the apparatus of FIG. 1;

FIG. 4 is a view showing the structure of a pipe system of the apparatus of FIG. 1;

FIG. 5 is a view showing a process of the substrate chucking operation of the apparatus of FIG. 1;

FIG. 6 is a view showing a process of the substrate chucking operation of the apparatus of FIG. 1;

FIG. 7 is a view showing a process of the substrate chucking operation of the apparatus of FIG. 1;

FIG. 8 is a view showing a process of the substrate chucking operation of the apparatus of FIG. 1;

FIG. 9 is a plan view showing the structure of a substrate chucking apparatus according to a second embodiment of the present invention;

FIG. 10 is a side view showing the structure of the apparatus of FIG. 9;

FIG. 11 is a partial enlarged view of an entire-surface chucking portion in the apparatus of FIG. 9;

FIG. 12 is a plan view showing the structure of a conventional substrate chucking apparatus;

FIG. 13 is a side view showing the structure of the apparatus of FIG. 12;

FIG. 14 is a view showing the hang of the outer peripheral portion of a substrate which occurs in the apparatus of FIG. 12;

FIG. 15 is a plan view showing the structure of a conventional substrate chucking apparatus;

FIG. 16 is a partial enlarged view of a chucking surface in an entire-surface chucking portion in the apparatus of FIG. 12;

FIG. 17 is a view showing chucking of a warped substrate in the apparatus of FIG. 12; and

FIG. 18 is a view showing the structure of a conventional substrate chucking apparatus.

### DETAILED DESCRIPTION OF THE INVENTION

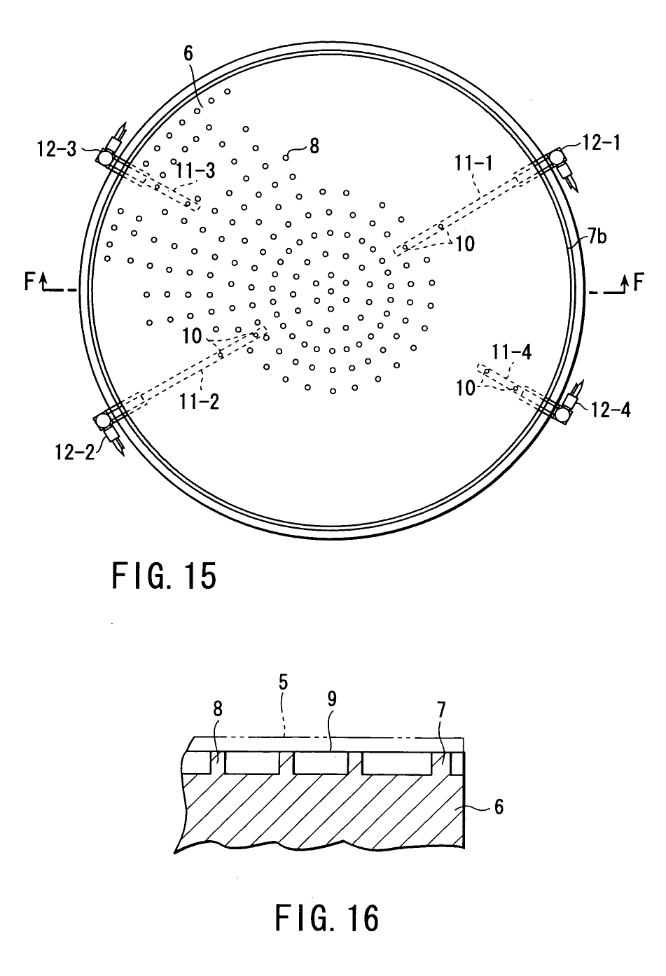

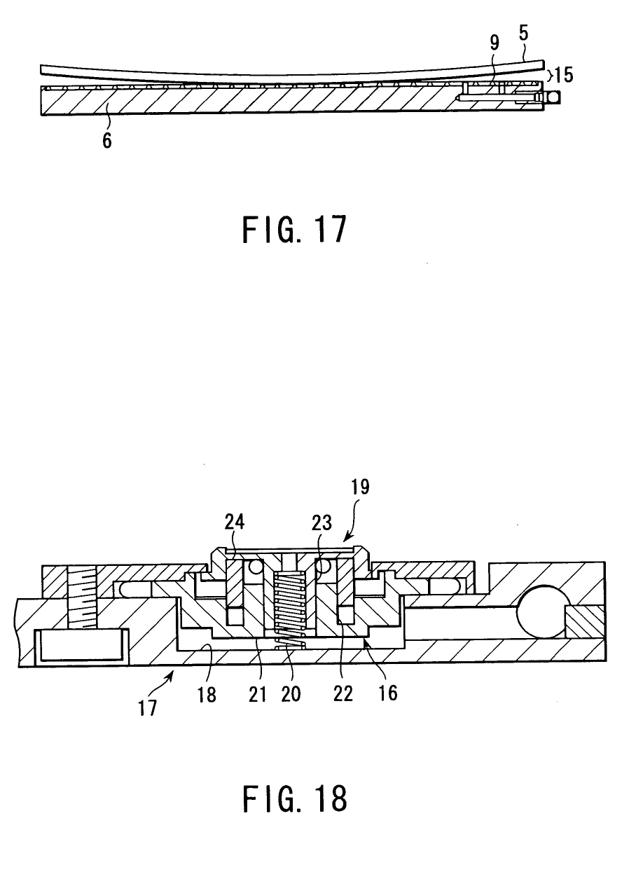

The first embodiment of the present invention will be described with reference to the drawing. The same portions as in FIG. 15 are denoted by the same reference numerals.

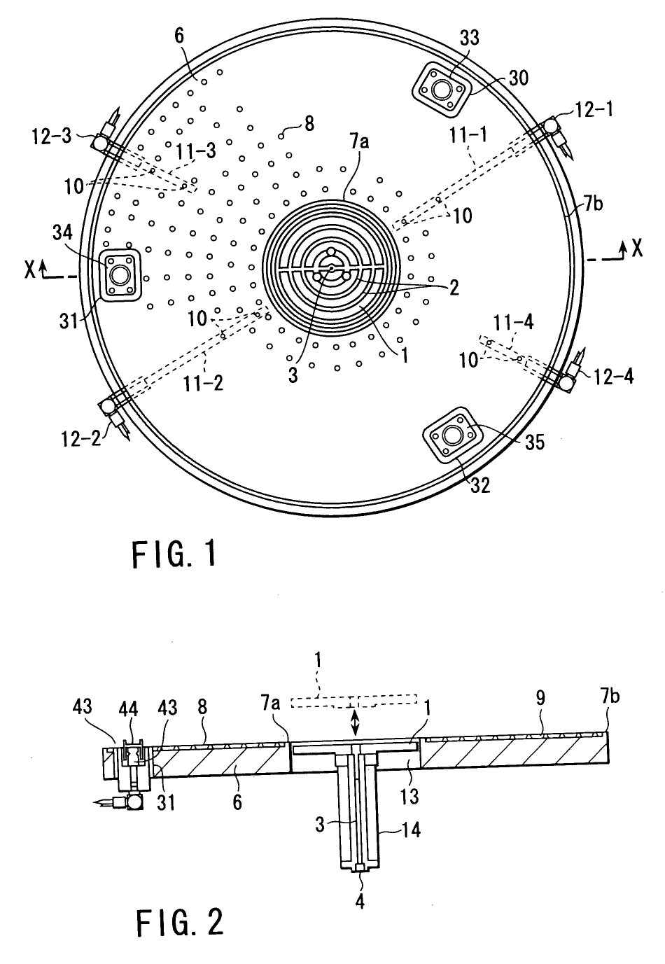

FIG. 1 is a plan view showing the structure of a substrate chucking apparatus, and FIG. 2 is a sectional view taken along the line X-X of the same. The first embodiment shows a case wherein a substrate chucking apparatus which chucks and holds the entire surface of a semiconductor wafer as, e.g., a disk-like substrate 5, is applied to a wafer holding stage.

An entire-surface chucking portion 6 is made of a high-hardness material such as a ceramic material to have a disk-like shape. Projecting banks 7a and 7b are formed on the innermost and outermost peripheral portions, respectively, of the entire-surface chucking portion 6. The banks 7a and 7b serve as chucking pads which maintain hermeticity between the substrate 5 and entire-surface chucking portion 6 when a notched semiconductor wafer is placed on the entire-surface chucking portion 6 as a substrate, and chuck the entire surface of the substrate 5.

A plurality of fine columnar projections 8 are formed on the entire upper surface of the entire-surface chucking portion 6, as shown in the partially enlarged view of FIG. 16. The banks 7a and 7b are flush with the projections, thus forming a chucking surface 9 which chucks and holds the substrate 5 with high flatness.

The entire-surface chucking portion 6 has four exhaust channels 11-1 to 11-4 communicating with exhaust holes 10 formed in the upper surface to chuck the substrate 5. The exhaust channels 11-1 to 11-4 are connected to an exhaust device such as a vacuum pump through respective joints 12-1 to 12-4 arranged on the outer peripheral portion of the entire-surface chucking portion 6.

A hole portion 13 is formed inside the bank 7a formed at the central portion of the entire-surface chucking portion 6. A substrate transfer portion 14 is provided in the hole portion 13. A plurality of grooves 2 to chuck the substrate 5 are formed in a chucking surface 1 of the substrate transfer portion 14. Each groove 2 communicates with an exhaust port 4 through an exhaust path 3. The chucking surface 1 of the substrate transfer portion 14 moves upper and down vertically with respect to the chucking surface 9 of the entire-surface chucking portion 6.

A plurality of, e.g., three pad holes 30 to 32, are formed near the outer periphery of the entire-surface chucking portion 6 equiangularly along the bank 7b at the outermost peripheral portion. Each of the pad holes 30 to 32 is quadrilateral. Correcting pad portions (also to be referred to as retractable pads) 33 to 35 are arranged in the pad holes 30 to.32, respectively.

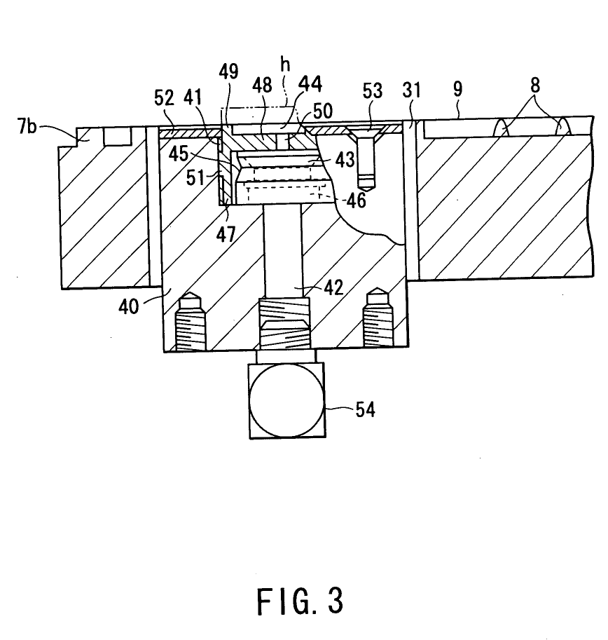

FIG. 3 is an enlarged view showing the structure of each of the correcting pad portions 33 to 35.

A foundation 40 is made of a metal material, and has a large-diameter pad accommodating hole 41 in its upper portion. A small-diameter exhaust channel 42 is formed under the pad accommodating hole 41.

A cylindrical elastic member 43 which forms an exhaust channel, and a pad 44 having a suction-cup-like upper portion are accommodated in the pad accommodating hole 41. The pad 44 has a bottomed cylindrical shape, and a small-diameter exhaust hole 50 is formed in the central portion of a pad bottom portion 48 of the pad 44 which corresponds to the bottom portion. The elastic member 43 is clamped between the pad bottom portion 48 and pad accommodating hole 41.

The elastic member 43 is made of a material such as silicone rubber. The elastic member 43 is cylindrical and has a narrow portion 45 on its outer surface. Since the narrow portion 45 is formed, the elastic member 43 can expand and contract smoothly in the vertical direction. An exhaust hole 46 through which the exhaust channel 42 and exhaust hole 50 communicate with each other is formed in the elastic member 43.

The pad 44 is made of, e.g., engineering plastics which is a rigidity member. The pad 44 integrally has a cylinder 47 and the pad bottom portion 48. The pad bottom portion 48 is arranged inside the cylinder 47 slightly below a pad upper surface 49. Thus, the pad 44 forms a suction cup portion.

The outer diameter of the cylinder 47 is formed slightly smaller than the diameter of the pad accommodating hole 41. Thus, the pad 44 is accommodated in the pad accommodating hole 41 to moved upward/downward vertically and oscillatable. The oscillating angle can be increased if the fitting space for the pad accommodating hole 41 and pad 44 is increased.

A flange 51 is formed on the outer side surface of the cylinder 47. The outer surface of the flange 51 is in surface contact with the inner wall of the pad accommodating hole 41, so that the flange 51 can slide vertically in FIG. 3.

A lid 52 is fixed to the foundation 40 with screws 53. The lid 52 has a circular opening projecting slightly inwardly from the edge of the opening of the pad accommodating hole 41. The circular opening has a diameter smaller than the diameter of the pad accommodating hole 41 and larger than the outer diameter of the cylinder 47 of the pad 44. The lid 52 abuts against the flange 51 to prevent the pad 44 from disengaging from the pad accommodating hole 41.

The exhaust channel 42 is connected to the exhaust device through a joint 54. When the exhaust device is actuated, air from the pad 44 is exhausted from the joint 54 through the exhaust channel 42 and exhaust holes 46 and 50.

The foundation 40 is fixed to the entire-surface chucking portion 6.

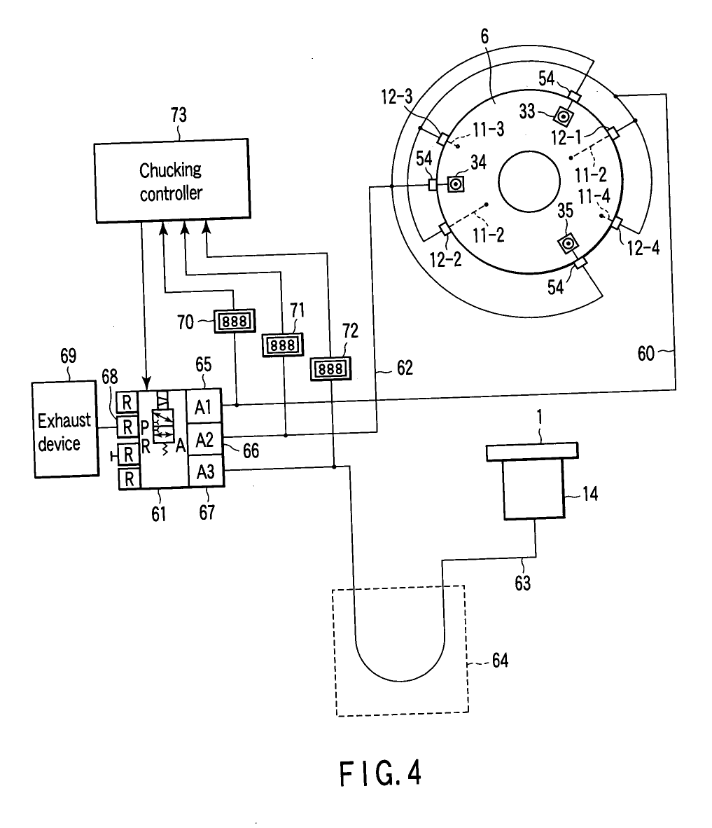

FIG. 4 is a view showing the structure of a pipe system. The joints 12-1 to 12-4 are commonly connected to an exhaust channel 60, and then to a solenoid valve 61 through the exhaust channel 60. The joints 54 respectively connected to the correcting pad portions 33 to 35 are commonly connected to an exhaust channel 62, and then to the solenoid valve 61 through the exhaust channel 62. The exhaust port 4 of the substrate transfer portion 14 is connected to the solenoid valve 61 through an exhaust channel 63. A vertical cable bearing 64 is arranged midway along the exhaust channel 63.

The solenoid valve 61 has three inner solenoid valves in one manifold. The three inner solenoids are connected to the exhaust channels 60, 62, and 63, respectively. For example, the exhaust channels 60, 62, and 63 are connected to A₁, A₂, and A₃ ports 65, 66, and 67, respectively, of the manifold of the solenoid valve 61.

A P port 68 of the manifold of the solenoid valve 61 is connected to an exhaust device 69 such as a vacuum pump.

Upon operation of the three inner solenoids, the solenoid valve 61 switches the exhaust channels 60, 62, and 63 respectively connected to the A₁, A₂, and A₃ ports 65, 66, and 67 independently to the exhaust device 69 connected to the P port 68.

The exhaust channels 60, 62, and 63 which form three systems are provided with three vacuum sensors 70 to 72, respectively. The vacuum sensors 70 to 72 detect the pressures in the exhaust channels 60, 62, and 63, respectively. When the pressures in the exhaust channels 60, 62, and 63 become less than preset pressure values, the vacuum sensors 70 to 72 output electrical signals indicating that the interiors of the exhaust channels 60, 62, and 63 are set in the vacuum state.

A chucking controller 73 controls the operations of the inner solenoid valves of the solenoid valve 61, and performs switching control of the exhaust channels 60, 62, and 63 to the exhaust device 69 connected to the P port 68. The chucking controller 73 also controls the vertical movement of the substrate transfer portion 14.

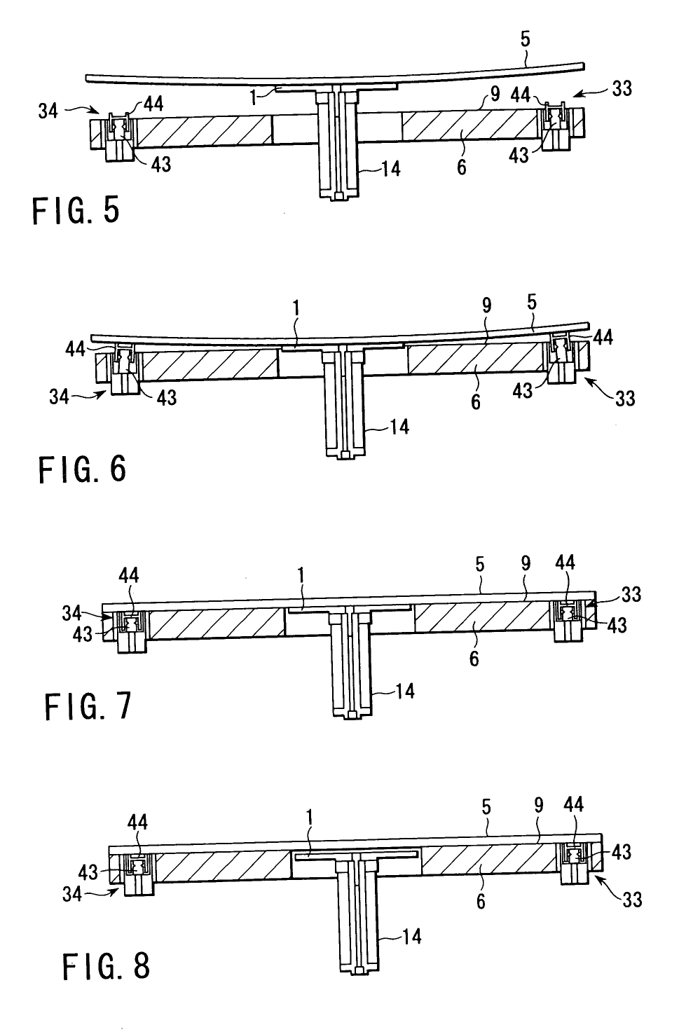

The operation of the apparatus having the above structure will be described with reference to the process views of the substrate chucking operation shown in FIGS. 5 to 8. In FIG. 1, only one correcting pad portion 34 is arranged in one sectional direction of the entire-surface chucking portion 6. FIGS. 5 to 8 show the two correcting pad portions 33 and 36 for facilitating understanding of the substrate chucking operation of this apparatus.

First, the substrate transfer portion 14 is controlled by the chucking controller 73 to move upward to a position higher than the chucking surface 9, as shown in FIG. 5. In this state, the substrate 5 is placed on the chucking surface 1 of the substrate transfer portion 14 by a transporting means (not shown) such as a robot hand.

The chucking controller 73 performs switching control of the inner solenoid valves of the solenoid valve 61, and connects the exhaust channel 63 to the exhaust device 69. Thus, when the exhaust device 69 performs exhaust operation, the central portion of the substrate 5 is chucked and held on the chucking surface 1 of the substrate transfer portion 14, as shown in FIG. 5.

The vacuum sensor 72 detects whether or not the interior of the exhaust channel 63 is set in the vacuum state. When it is detected that the interior of the exhaust channel 63 is set in the vacuum state, the vacuum sensor 72 outputs an electrical signal indicating the vacuum state. When the electrical signal is input to the chucking controller 73 from the vacuum sensor 72 within a predetermined period of time after the start of the exhaust operation of the exhaust device 69, the chucking controller 73 determines that the substrate transfer portion 14 has successfully chucked the substrate 5.

At this time, the internal pressures of the elastic members 43 become equal to the atmospheric pressure. Thus, the pads 44 are pushed upward by the elastic forces of the elastic members 43. The pad upper surfaces 49 of the pads 44 protrude from the chucking surface 9 of the entire-surface chucking portion 6 by a height h. For example, the height h is set to be larger than the distance by which the chucking surface 9 of the entire-surface chucking portion 6 and a warped substrate 5 are separate from each other when the substrate 5 is placed on the entire-surface chucking portion 6.

Subsequently, the chucking controller 73 moves the substrate transfer portion 14 downward, as shown in FIG. 6, and stops it at a predetermined height where the chucking surface 1 of the substrate transfer portion 14 is a little upward flush with the chucking surface 9.

When the substrate transfer portion 14 moves downward as shown in FIG. 6, the lower surface of the substrate 5 comes close to or in contact with the pad upper surfaces 49 of the pads 44 of the correcting pad portions 33 to 35.

The elastic members 43 deformed, and the pads 44 chuck the substrate 5 in contact with it, while oscillating, to naturally follow its warp.

Simultaneously, the chucking controller 73 performs switching control of the inner solenoid valves of the solenoid valve 61, and connects the exhaust channel 62 to the exhaust device 69. Thus, when the exhaust device 69 performs exhaust operation, the correcting pad portions 33 to 35 exhaust air through the exhaust channels 42 and exhaust holes 46 and 50, as shown in FIG. 3.

At this time, the respective pads 44 are chucked by the lower surface of the substrate 5 due to the air suction operation.

At the same time, upon control operation of the chucking controller 73, the substrate transfer portion 14 moves the chucking surface 1 downward until the chucking surface 1 becomes flush with the chucking surface 9 of the entire-surface chucking portion 6, as shown in FIG. 7.

In the pads 44, the pressures of the interiors of the elastic members 43 become negative due to the suction operation of the exhaust device 69. Due to the negative pressure, the elastic members 43 are collapsed largely at their narrow portions 45, so that the respective pads 44 retract in the foundations 40, as shown in FIG. 7.

As the pads 44 move downward, the peripheral portion of the substrate 5 is retracted toward the entire-surface chucking portion 6, and abuts against the bank 7b.

At this time, the chucking controller 73 receives an electrical signal from the vacuum sensor 71 within a predetermined period of time after the start of the exhaust operation, and determines that the respective correcting pad portions 33 to 35 have successfully chucked the substrate 5.

When the pads 44 chuck the lower surface of the substrate 5 in this manner, the pad upper surfaces 49 are closed by the substrate 5. Thus, the exhaust holes 50 of the pads 44 and the exhaust holes 46 and exhaust channels 42 of the elastic members 43 are sealed.

Subsequently, the chucking controller 73 performs switching control of the inner solenoid valves of the solenoid valve 61, and connects the exhaust channel 60 to the exhaust device 69. By this exhaust operation, air in the gap formed by the entire-surface chucking portion 6 and substrate 5 is exhausted through the respective exhaust holes 10, and the lower surface of the substrate 5 is chucked by and held on the entire-surface chucking portion 6.

At this time, the chucking controller 73 receives an electrical signal from the vacuum sensor 70 to 72 within a predetermined period of time after the start of the exhaust operation, and determines that the substrate 5 has been successively chucked by the entire-surface chucking portion 6. The chucking controller 73 switches the inner solenoid valves of the solenoid valve 61, and separates the exhaust device 69 and exhaust port 63 from each other. Thus, the substrate transfer portion 14 stops chucking the substrate 5.

Subsequently, the chucking controller 73 detects that the electrical signal output from the vacuum sensor 72 disappears, and confirms that chucking by the substrate transfer portion 14 is stopped.

The substrate transfer portion 14 then moves downward below the chucking surface 9 of the entire-surface chucking portion 6, as shown in FIG. 8, by the control operation of the chucking controller 73.

The substrate transfer portion 14 moves downward to avoid a slight difference in height between the chucking surface 9 of the entire-surface chucking portion 6 and the chucking surface 1 of the substrate transfer portion 14 that can be caused by a mechanical error, so that no unnecessary stress is applied to the substrate 5.

If the vacuum sensors 70 to 72 do not output electrical signals within the predetermined period of time after the start of the exhaust operation, the chucking controller 73 determines that the substrate 5 is not successfully chucked by the correcting pad portions 33 to 35, substrate transfer portion 14, and/or entire-surface chucking portion 6. For example, on the basis of the determination result of substrate chucking, if it is determined that chucking is defective, the chucking controller 73 outputs an instruction to disable testing, or an instruction to subject the substrate 5 to a disposal process because the substrate 5 is defective.

In this manner, in the first embodiment described above, the correcting pad portions 33 to 35, each having the pad 44 which can oscillate and move vertically and the elastic member 43 which is expanded or contracted by the negative pressure caused by air exhaust to move the pad 44 upward or downward, are arranged along the bank 7b at the outermost peripheral portion of the entire-surface chucking portion 6.

Thus, even if the substrate 5 warps upward or downward and floats partly from the chucking surface 9 of the entire-surface chucking portion 6, the peripheral portion of the floating substrate 5 can be forcibly urged with the correcting pad portions 33 to 35 against the bank 7b of the entire-surface chucking portion 6, to improve the suction effect of the entire-surface chucking portion 6. Consequently, erroneous chucking by the entire-surface chucking portion 6 can be prevented.

When the entire surface of the substrate 5 is chucked by the entire-surface chucking portion 6, the substrate 5 can be chucked and held by the large number of projections 8 and banks 7a and 7b flush throughout the entire surface of the entire-surface chucking portion 6.

The pads 44 of the correcting pad portions 33 to 35 can move vertically and oscillate. Even if the substrate 5 warps, the pads 44 can change their directions substantially perpendicularly to the lower surface of the substrate 5 so as to follow the warp of the substrate 5, so that they can chuck the lower surface of the substrate 5 reliably.

The elastic members 43 of the correcting pad portions 33 to 35 have the narrow portions 45 on their outer surfaces. Thus, the elastic members 43 can be expanded and contracted in the vertical direction and oscillate smoothly in the horizontal direction. Also, a large expansion/contraction amount in the vertical direction can be obtained. Therefore, when correcting the warp of the substrate 5, no excessive force acts on the substrate 5.

The entire-surface chucking portion 6 is made of a high-hardness material, e.g., a ceramic material, and is machined to form the chucking surface 9 having high flatness. Therefore, the entire-surface chucking portion 6 can chuck and hold the substrate 5 with high flatness. When the surface of the substrate 5 is to be microscopically observed from above, the entire surface of the substrate 5 can be set in focus, and good observation can be performed.

As the substrate 5 is supported with the plurality of projections 8 formed on the chucking surface 9 of the entire-surface chucking portion 6, microdust attaches to the lower surface of the substrate 5 at a very low possibility.

The second embodiment of the present invention will be described with reference to the drawings. The same portions as in FIGS. 1 and 2 are denoted by the same reference numerals, and a detailed description thereof will be omitted.

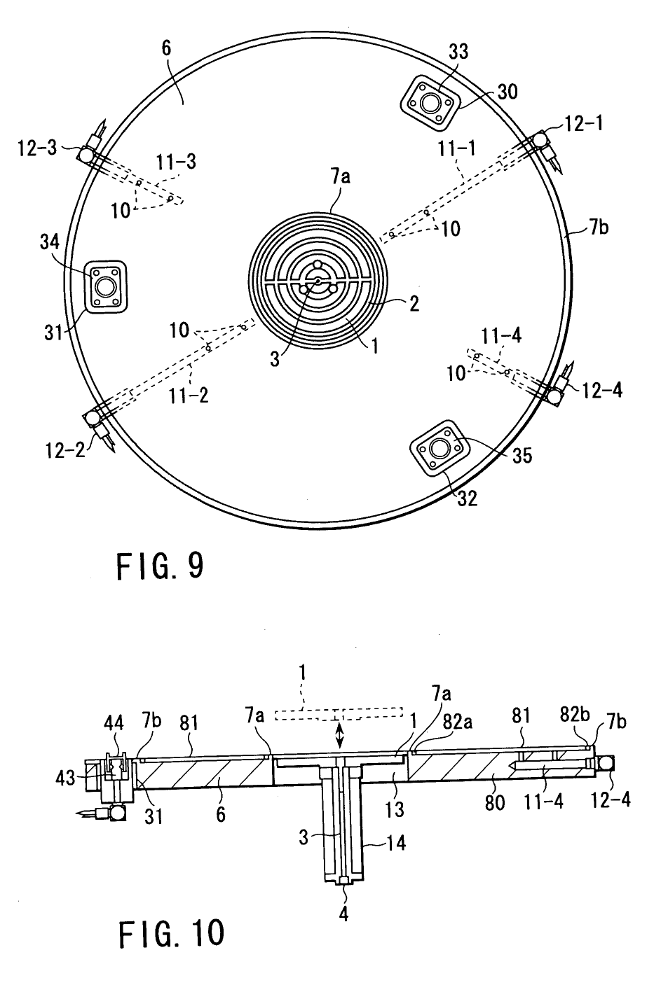

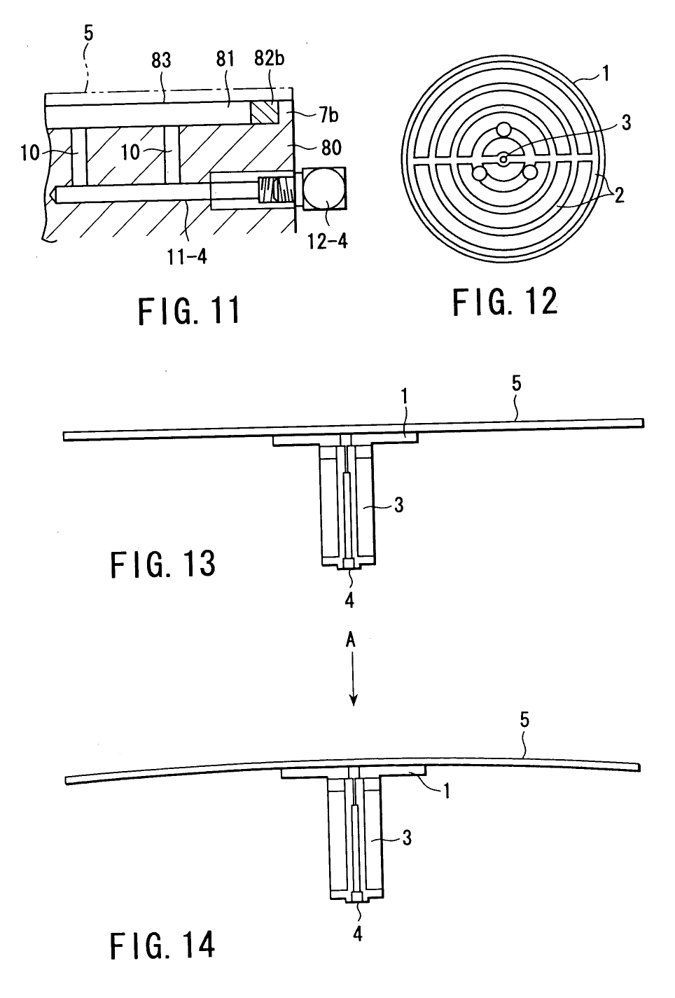

FIG. 9 is a plan view showing the structure of a substrate chucking apparatus, FIG. 10 is a sectional view of the structure, and FIG. 11 is a partial enlarged view of an entire-surface chucking portion 6. According to the second embodiment, in place of the plurality of projections 8 formed on the entire surface of the entire-surface chucking portion 6 described in the first embodiment, an entire-surface chucking plate 81 made of an air-permeable porous material, e.g., porous Teflon, is arranged on the upper surface of the entire-surface chucking portion 6.

The entire-surface chucking portion 6 includes a disk-like foundation portion 80, and the entire-surface chucking plate 81 arranged on the foundation portion 80. The foundation portion 80 is made of a metal material, e.g., aluminum, having a predetermined strength. A surface 83 of the entire-surface chucking plate 81 has high flatness. The surface 83 of the entire-surface chucking plate 81 is flush with banks 7a and 7b. In order to improve the exhaust efficiency, a large number of chucking holes may be formed, or a large number of annular exhaust grooves may be formed concentrically.

Hermetic portions 82a and 82b are formed between the innermost peripheral portion of the entire-surface chucking plate 81 and the bank 7a, and between the outermost peripheral portion of the entire-surface chucking plate 81 and the bank 7b, respectively, to prevent air leakage from the side surface of the entire-surface chucking plate 81. The hermetic portions 82a and 82b are formed by impregnating the side surface of the entire-surface chucking plate 81 with, e.g., a silicone-based sealed member or a fluidized resin such as an adhesive, to seal fine holes in the porous material.

With this arrangement, the same effect as that of the first embodiment described above can be obtained.

In the second embodiment, the entire-surface chucking plate 81 of the entire-surface chucking portion 6 uses a porous material. Therefore, a substrate 5 can be chucked and held in tight contact by the entire surface of the entire-surface chucking plate 81 of the entire-surface chucking portion 6, and can be held on the entire-surface chucking portion 6 with high flatness without causing any distortion.

As the porous material, the entire-surface chucking plate 81 uses, e.g., porous Teflon. Teflon has lower hardness than that of the substrate 5 formed of a silicon wafer. Thus, the substrate 5 will not be damaged at all.

The present invention is not limited to the first and second embodiments described above, but can be modified in the following manner.

For example, at least two correcting pads suffice. If a large number of, e.g., three or more, correcting pads are provided, the substrate 5 that has been warped at the start of entire-surface chucking can be corrected in flatness reliably, and erroneous entire-surface chucking can be prevented.

The entire-surface chucking portion 6 in each embodiment described above chucks and holds a substrate having a diameter of, e.g., 300 mm. Alternatively, the entire-surface chucking portion 6 may also chuck and hold a substrate having a diameter of, e.g., 200 mm. In this case, a round bank for a substrate having a diameter of 200 mm is formed between the banks 7a and 7b on the entire-surface chucking portion 6. At least two correcting pads are arranged along this bank on the bank 7a side.

In each of the correcting pad portions 33 to 35, the structure that enables the pad 44 to move vertically and oscillate is not limited to the structures of the embodiments described above. For example, a diaphragm, bellows tube, or the like shown in, e.g., Jpn. Pat. Appln. KOKAI Publication No. 10-86086 may be used.

The air exhaust amounts of the correcting pad portions 33 to 35 may be adjusted in accordance with conditions such as the elasticities of the elastic members 43 and the thickness of the substrate 5. Then, even when the conditions change, the substrate 5 can be chucked reliably.

To chuck and hold the substrate 5 with high flatness on the entire-surface chucking portion 6, the plurality of projections 8 are formed. However, the present invention is not limited to this, and a plurality of convex portions may be formed radially in the radial direction of the entire-surface chucking portion 6. Alternatively, a plurality of arcuate convex portions may be formed on the entire-surface chucking portion 6.

The present invention is used for surface defect inspection of a glass substrate employed in a flat panel display such as a liquid crystal display and organic electroluminescent display, line-width inspection and pattern inspection of the display electrodes of pixels formed on the glass substrate, and the like.

1. A substrate chucking apparatus comprising:
an entire-surface chucking portion which includes a chucking surface that chucks and holds a substrate to maintain flatness of the substrate, and has a hole portion formed at a central portion;
a substrate transfer portion which is arranged in the hole portion of the entire-surface chucking portion to up/down possible, and chucks and holds the substrate and up/downs, to transfer the substrate with respect to the entire-surface chucking portion; and
at least three correcting pad portions which includes cylindrical pads and tubular elastic members, the cylindrical pads are arranged along an outermost peripheral portion of the entire-surface chucking portion and up/down possible with respect to the chucking surface of the entire-surface chucking portion, and formed a suction-cup-shaped upper portion, the tubular elastic member swingably supports the cylindrical pads when the elastic member moves upward, the at least three correcting pad portions correcting the substrate so as to be parallel to the entire-surface chucking portion when a negative pressure generated upon chucking of the substrate collapses the elastic members.

2. A substrate chucking apparatus according to claim 1, further comprising:
the correcting pad portions includes a pad accommodating hole in which the cylindrical pads can move, the cylindrical pads are so formed as to have an outer diameter smaller than an inner diameter of the pad accommodating hole, a projection which can move in contact with the pad accommodating holes and is shorter than the cylindrical pad is formed on an outer side surface of the cylindrical pads, and a lid having an opening with a diameter smaller than the inner diameter of the cylindrical pads accommodating hole which abuts against the projection to prevent the cylindrical pads from disengaging from the pads accommodating hole and larger than the outer diameter of the cylindrical pads are provided below the chucking surface of the entire-surface chucking portion.

3. A substrate chucking apparatus comprising:
an entire-surface chucking portion which includes a chucking surface that chucks and holds a substrate to maintain flatness of the substrate and has a hole portion formed at a central portion of the entire-surface chucking portion;
a substrate transfer portion which is arranged in the hole portion of the entire-surface chucking portion to up/downs possible, and chucks and holds the substrate and up/downs, to transfer the substrate with respect to the entire-surface chucking portion;
a correcting pad portions which correct the substrate so as to be parallel to the chucking surface of the entire-surface chucking portion; and
a chucking controller which independently switches chucking operation by the entire-surface chucking portion through an exhaust system connected to the entire-surface chucking portion, chucking operation by the substrate transfer portion through an exhaust system connected to the substrate transfer portion, and chucking operation by the correcting pad portions through an exhaust system connected to the correcting pad portions.

4. A substrate chucking apparatus according to claim 3, wherein the control means outputs an indication of undetectability if it is determined that the entire-surface chucking portion has not succeeded in chucking the substrate within a predetermined period of time.

5. A substrate chucking apparatus according to claim 3, wherein the control means determines unsatisfactory chucking due to a failure of the substrate and gives an instruction for disposing the substrate if it is determined that the entire-surface chucking portion has not succeeded in chucking the substrate within a predetermined period of time.

6. A substrate chucking apparatus according to claim 3, wherein the control means adjusts an air exhaust amount of the third exhaust system in accordance with a thickness of the substrate.

7. A substrate chucking apparatus according to claim 3, wherein the control means makes the substrate transfer portion perform chucking operation through the second exhaust system after the substrate transfer portion has received the substrate, lowers the substrate transfer portion such that a chucking surface of the substrate transfer portion is substantially flush with the chucking surface of the entire-surface chucking portion if it is determined that the substrate is chucked onto the chucking surface of the substrate transfer portion, makes the third exhaust system perform exhaust operation, and stops exhaust operation of the second exhaust system and makes the entire-surface chucking portion perform chucking operation through the first exhaust system if it is determined that the substrate is chucked onto the correcting pad portions.

8. A substrate chucking apparatus according to claim 3, wherein the control means performs control to move the correcting pad portions below a chucking surface of a foundation.

9. A substrate chucking apparatus according to claim 3, wherein the chucking controller starts the chucking operation by the entire-surface chucking portion after it is determined that chucking of the substrate by the correcting pad portions is successful.

10. A substrate chucking apparatus according to claim 3, wherein the chucking controller stops the chucking operation by the substrate transfer portion after it is determined that chucking of the substrate by the correcting pad portions is successful.
